(19) United States
(12) Patent Application Publication
(10) Pub. No.: US 2025/0263593 A1
(43) Pub. Date: Aug. 21, 2025

(54) ABRASIVE GRAINS AND METHOD FOR SELECTING SAME, POLISHING LIQUID, MULTI-LIQUID TYPE POLISHING LIQUID, POLISHING METHOD, COMPONENT MANUFACTURING METHOD, AND SEMICONDUCTOR COMPONENT MANUFACTURING METHOD

(71) Applicant: Resonac Corporation, Minato-ku, Tokyo (JP)

(72) Inventors: Hiromu KUBO, Minato-ku, Tokyo (JP); Sangchul LEE, Minato-ku, Tokyo (JP); Koichi KAGESAWA, Minato-ku, Tokyo (JP); Satoyuki NOMURA, Minato-ku, Tokyo (JP)

(21) Appl. No.: 18/857,322

(22) PCT Filed: May 9, 2023
(86) PCT No.: PCT/JP2023/017464

§ 371 Date: Oct. 16, 2024

(30) Foreign Application Priority Data
Oct. 27, 2022 (JP) 2022-172587

(51) Int. Cl. C09K 3/14; H01L 21/3105

(52) U.S. Cl. CPC C09K 3/1409; C09K 3/1463; H01L 21/31053

(57) ABSTRACT

A selection method for abrasive grains, in which the abrasive grains contain cerium, and the abrasive grains are selected on the basis of an average value of a positron lifetime as measured by a positron annihilation method. Abrasive grains containing cerium, in which an average value of a positron lifetime as measured by a positron annihilation method is 360 ps or less. A polishing liquid containing the above-described abrasive grains and water. A multi-pack polishing liquid having a first liquid containing the above-described abrasive grains and water, and a second liquid containing a component other than the above-described abrasive grains and water, and water. A polishing method including polishing a member to be polished by using the above-described polishing liquid.

### TECHNICAL FIELD

The present disclosure relates to abrasive grains, a selection method therefor, a polishing liquid, a multi-pack polishing liquid, a polishing method, a method for manufacturing a component, a method for manufacturing a semiconductor component, and the like.

### BACKGROUND ART

In the manufacturing steps for electronic devices in recent years, the importance of processing technologies for density increase, micronization, and the like is increasing more and more. CMP (chemical mechanical polishing) technology, which is one of the processing technologies, has become an essential technology for formation of a shallow trench isolation (STI), flattening of a pre-metal insulating material or an interlayer insulating material, formation of a plug or an embedded metal wiring, or the like, in the manufacturing steps for electronic devices. As a polishing liquid used in CMP, a polishing liquid that contains abrasive grains containing cerium is known (see, for example, Patent Literatures 1 and 2 below).

### CITATION LIST

### Patent Literature

Patent Literature 1: Japanese Unexamined Patent Publication No. H10-106994
Patent Literature 2: Japanese Unexamined Patent Publication No. H08-022970

### SUMMARY OF INVENTION

### Technical Problem

It is required for a polishing liquid containing abrasive grains to adjust a polishing rate of a material to be polished depending on the use applications, and a novel method for adjusting a polishing rate of a material to be polished is required. Furthermore, there is a case where it is required for the polishing liquid containing abrasive grains to increase a polishing rate of silicon oxide in a blanket wafer having no pattern.

An object of an aspect of the present disclosure is to provide a selection method for abrasive grains capable of adjusting a polishing rate of a material to be polished. An object of another aspect of the present disclosure is to provide abrasive grains having a high polishing rate of silicon oxide in a blanket wafer. An object of another aspect of the present disclosure is to provide a polishing liquid containing the above-described abrasive grains. An object of another aspect of the present disclosure is to provide a multi-pack polishing liquid using the above-described abrasive grains. An object of another aspect of the present disclosure is to provide a polishing method using the above-described polishing liquid. An object of another aspect of the present disclosure is to provide a method for manufacturing a component by using the polished member polished by the above-described polishing method. An object of another aspect of the present disclosure is to provide a method for manufacturing a semiconductor component by using the polished member polished by the above-described polishing method.

### Solution to Problem

The present disclosure relates to the following [1] to [17] and the like in several aspects.
[1] A selection method for abrasive grains, in which the abrasive grains contain cerium, and the abrasive grains are selected on the basis of an average value of a positron lifetime as measured by a positron annihilation method.
[2] The selection method for abrasive grains described in [1], in which the abrasive grains contain cerium oxide.
[3] Abrasive grains containing cerium, in which an average value of a positron lifetime as measured by a positron annihilation method is 360 ps or less.
[4] The abrasive grains described in [3], in which the average value of the positron lifetime as measured by the positron annihilation method is 300 to 360 ps.
[5] The abrasive grains described in [3] or [4], in which a crystallite diameter is 30 nm or more.
[6] The abrasive grains described in any one of [3] to [5], in which a crystallite diameter is 36 to 50 nm.
[7] The abrasive grains described in any one of [3] to [6], containing cerium oxide.
[8] The abrasive grains described in any one of [3] to [7], containing cerium oxide derived from a cerium complex of trimesic acid.
[9] The abrasive grains described in any one of [3] to [8], containing cerium oxide derived from cerium hydroxide.
[10] The abrasive grains described in any one of [3] to [9], containing cerium oxide derived from cerium carbonate.
[11] The abrasive grains described in any one of [3] to [10], containing cerium oxide derived from cerium oxycarbonate.
[12] A polishing liquid containing the abrasive grains selected by the selection method for abrasive grains described in [1] or [2] or the abrasive grains described in any one of [3] to [11], and water.
[13] A multi-pack polishing liquid having a first liquid containing abrasive grains and water, and a second liquid containing a component other than the abrasive grains and water, and water, in which the abrasive grains are the abrasive grains selected by the selection method for abrasive grains described in [1] or [2] or the abrasive grains described in any one of [3] to [11].
[14] A polishing method including polishing a member to be polished by using the polishing liquid described in [12].
[15] The polishing method described in [14], in which the member to be polished contains silicon oxide.
[16] A method for manufacturing a component, including obtaining a component by using a polished member polished by the polishing method described in [14] or [15].
[17] A method for manufacturing a semiconductor component, including obtaining a semiconductor component by using a polished member polished by the polishing method described in [14] or [15].

### Advantageous Effects of Invention

According to an aspect of the present disclosure, it is possible to provide a selection method for abrasive grains capable of adjusting a polishing rate of a material to be polished. According to another aspect of the present disclosure, it is possible to provide abrasive grains having a high polishing rate of silicon oxide in a blanket wafer. According to another aspect of the present disclosure, it is possible to provide a polishing liquid containing the above-described abrasive grains. According to another aspect of the present disclosure, it is possible to provide a multi-pack polishing liquid using the above-described abrasive grains. According to another aspect of the present disclosure, it is possible to provide a polishing method using the above-described polishing liquid. According to another aspect of the present disclosure, it is possible to provide a method for manufacturing a component by using the polished member polished by the above-described polishing method. According to another aspect of the present disclosure, it is possible to provide a method for manufacturing a semiconductor component by using the polished member polished by the above-described polishing method.

### DESCRIPTION OF EMBODIMENTS

Hereinafter, embodiments of the present disclosure will be described. However, the present disclosure is not limited to the following embodiments.

In the present specification, a numerical range that has been indicated by use of “to” indicates the range that includes the numerical values which are described before and after “to”, as the minimum value and the maximum value, respectively. “A or more” in the numerical range means A and a range of more than A. “A or less” in the numerical range means A and a range of less than A. In the numerical ranges that are described stepwise in the present specification, the upper limit value or the lower limit value of the numerical range of a certain stage can be arbitrarily combined with the upper limit value or the lower limit value of the numerical range of another stage. In the numerical ranges that are described in the present specification, the upper limit value or the lower limit value of the numerical range may be replaced with the value shown in Experimental Examples. “A or B” may include either one of A and B, and may also include both of A and B. Materials listed as examples in the present specification can be used singly or in combinations of two or more, unless otherwise specified. When a plurality of substances corresponding to each component exist in the composition, the content of each component in the composition means the total amount of the plurality of substances that exist in the composition, unless otherwise specified. The term “step” includes not only an independent step but also a step by which an intended action of the step is achieved, though the step cannot be clearly distinguished from other steps. The term “abrasive grains” means a collective entity of a plurality of particles, and for convenience, one particle constituting the abrasive grains may be referred to as an abrasive grain.

Abrasive grains and a selection method therefor of the present embodiment are abrasive grains used in a polishing liquid and a selection method therefor. In the abrasive grains and the selection method therefor of the present embodiment, the abrasive grains contain cerium. In the selection method for abrasive grains of the present embodiment, abrasive grains are selected on the basis of an average value of a positron lifetime (average positron lifetime) as measured by a positron annihilation method. The abrasive grains of the present embodiment have any numerical value as the average value of the positron lifetime (the positron lifetime of the abrasive grains) (average positron lifetime) as measured by a positron annihilation method, depending on the use application.

The present inventors have focused on the abrasive grains containing cerium and found that, by adjusting a average value of the positron lifetime of the abrasive grains as measured by a positron annihilation method, a polishing rate of a material to be polished in the case of polishing the material to be polished by using the abrasive grains can be adjusted. According to the abrasive grains and the selection method therefor of the present embodiment, abrasive grains can be selected on the basis of an average value of a positron lifetime as measured by a positron annihilation method, and a polishing rate of a material to be polished in the case of polishing the material to be polished by using such abrasive grains can be adjusted. According to the present embodiment, it is possible to provide a method for adjusting a polishing rate, the method including adjusting a polishing rate of a material to be polished on the basis of an average value of a positron lifetime (an average value of a positron lifetime as measured by a positron annihilation method) of the abrasive grains.

According to an embodiment of the abrasive grains and the selection method therefor of the present embodiment, the polishing rate of the material to be polished in a blanket wafer or a pattern wafer can be adjusted. According to an embodiment of the abrasive grains and the selection method therefor of the present embodiment, the polishing rate of the material to be polished can be adjusted so as to increase the polishing rate of the material to be polished, and the polishing rate of the material to be polished can also be adjusted so as to reduce the polishing rate of the material to be polished. According to an embodiment of the abrasive grains and the selection method therefor of the present embodiment, a polishing rate of an insulating material can be adjusted, and a polishing rate of silicon oxide can be adjusted.

The abrasive grains contain cerium (cerium element), and may contain a cerium compound. Examples of the cerium compound include cerium oxide, cerium hydroxide, cerium ammonium nitrate, cerium acetate, cerium sulfate (for example, cerium sulfate hydrate), cerium bromate, cerium bromide, cerium chloride, cerium oxalate, cerium nitrate, and cerium carbonate. From the viewpoint of easily adjusting the polishing rate of the material to be polished or the viewpoint of easily increasing the polishing rate of the material to be polished (such as the polishing rate of silicon oxide in a blanket wafer or the polishing rate of silicon oxide in a pattern wafer; the same applies hereinafter), the abrasive grains may contain cerium oxide. The cerium oxide may be CeO₂ (cerium(IV) oxide, ceria), and may be Ce₂O₃ (cerium(III) oxide).

The abrasive grains may contain cerium oxide derived from a cerium source, and may contain a fired product of a cerium source. As the cerium source, a cerium salt may be used, and a cerium complex may be used. The abrasive grains may contain cerium oxide derived from a cerium salt, and may contain cerium oxide derived from a cerium complex.

From the viewpoint of easily increasing the polishing rate of the material to be polished, the cerium complex may include a cerium complex of a compound A having a carbon chain (a complex having a ligand of the compound A and cerium). From the viewpoint of easily increasing the polishing rate of the material to be polished, the compound A may include at least one selected from the group consisting of a carboxy group and a carboxylate group. In this case, the number of carboxy groups or the total number of carboxy groups and carboxylate groups may be 1 to 4, 1 to 3, 2 to 4, 2 to 3, or 3 to 4, from the viewpoint of easily increasing the polishing rate of the material to be polished. From the viewpoint of easily increasing the polishing rate of the material to be polished, the compound A may have at least one selected from the group consisting of a linear (acyclic) carbon chain and a cyclic carbon chain, and may have a cyclic carbon chain. The cyclic carbon chain may be alicyclic, heterocyclic, or aromatic ring. From the viewpoint of easily increasing the polishing rate of the material to be polished, the compound A may have an aromatic ring. From the viewpoint of easily increasing the polishing rate of the material to be polished, the cerium complex may include a cerium complex of aromatic carboxylic acid, may include a cerium complex of benzenetricarboxylic acid, and may include a cerium complex of trimesic acid. The cerium complex may include metal organic frameworks.

Examples of the cerium source include cerium carbonate (excluding cerium oxycarbonate), cerium oxycarbonate, a cerium complex of trimesic acid, cerium acetate, cerium stearate, cerium nitrate, cerium sulfate, cerium oxalate, and cerium hydroxide. From the viewpoint of easily increasing the polishing rate of the material to be polished, the abrasive grains may contain at least one selected from the group consisting of cerium oxide derived from cerium carbonate (for example, a fired product of cerium carbonate), cerium oxide derived from cerium oxycarbonate (for example, a fired product of cerium oxycarbonate), cerium oxide derived from a cerium complex of trimesic acid (for example, a fired product of a cerium complex of trimesic acid), and cerium oxide derived from cerium hydroxide (for example, a fired product of cerium hydroxide). That is, the abrasive grains may be an embodiment containing cerium oxide derived from cerium carbonate, an embodiment containing cerium oxide derived from cerium oxycarbonate, an embodiment containing cerium oxide derived from a cerium complex of trimesic acid, or an embodiment containing cerium oxide derived from cerium hydroxide.

The abrasive grains of the present embodiment may be obtained by processing a raw material (raw material for obtaining abrasive grains) containing cerium, and for example, may be obtained by pulverizing a raw material (raw material for obtaining abrasive grains) containing cerium. A method for producing the abrasive grains of the present embodiment may include a processing step of processing a raw material (raw material for obtaining abrasive grains) containing cerium, and for example, may include a pulverization step of pulverizing a raw material (raw material for obtaining abrasive grains) containing cerium to obtain a pulverized product. The shape of the raw material containing cerium is not particularly limited, and may be, for example, a particulate shape, a fibrous shape, a flake shape, a liquid shape (for example, highly viscous liquid shape), or the like. The method for producing the abrasive grains of the present embodiment may include a classification step of classifying the pulverized product after the pulverization step. In the classification step, a coarse substance (for example, coarse particles) can be removed. The pulverizing method in the pulverization step is not particularly limited, and various pulverizing methods such as wet pulverization and dry pulverization can be used. The classification method in the classification step is not particularly limited, and examples thereof include centrifugal separation.

The method for producing the abrasive grains of the present embodiment may include a raw material preparation step of oxidizing the aforementioned cerium source (for example, a cerium salt) to obtain a raw material (raw material for obtaining abrasive grains) containing cerium before the processing step (for example, the pulverization step). Examples of the oxidation method include a firing method in which a cerium source is fired at 600 to 900° C. or the like; and a chemical oxidation method in which a cerium source is oxidized using an oxidizing agent such as hydrogen peroxide.

In the measurement of the positron lifetime, atomic-level defects, intermolecular gaps, pore structures, and the like can be evaluated by measuring the time until a positron incident on a material disappears. The average value of the positron lifetime is a component derived from a sample when a three-component analysis is performed using two components in total of the Kapton component and an adhesive component as radiation source components, after the positron lifetime is measured by a positron annihilation method. The average value of the positron lifetime can be used, for example, as an index of an average value of sizes of oxygen defects. The average value of the positron lifetime can be measured by the method described in Experimental Examples described below. The average value of the positron lifetime can be adjusted by production conditions of the abrasive grains, and the like. For example, as the firing temperature of the cerium source when a raw material (raw material for obtaining abrasive grains) containing cerium is obtained is higher, there is a tendency that the positron lifetime is smaller (shorter).

The present inventors have found that, by using abrasive grains having an average value of a positron lifetime as measured by a positron annihilation method of 360 ps or less, the polishing rate of silicon oxide is easily increased. An embodiment of the abrasive grains of the present embodiment contains cerium, in which an average value of a positron lifetime as measured by a positron annihilation method is 360 ps or less. According to such abrasive grains, the polishing rate of silicon oxide in a blanket wafer is easily increased. According to an embodiment of the abrasive grains of the present embodiment, in the evaluation method described in Experimental Examples described below, it is possible to obtain a polishing rate of silicon oxide in a blanket wafer of, for example, 25 nm/min or more (preferably, 30 nm/min or more, 50 nm/min or more, 70 nm/min or more, 90 nm/min or more, 100 nm/min or more, 110 nm/min or more, 120 nm/min or more, or the like).

According to an embodiment of the abrasive grains of the present embodiment, the polishing rate of silicon oxide in a pattern wafer is easily increased. According to an embodiment of the abrasive grains of the present embodiment, in the evaluation method described in Experimental Examples described below, it is possible to obtain a polishing rate of silicon oxide in a pattern region with L/S=50/50 of, for example, 15 nm/min or more (preferably, 20 nm/min or more, 25 nm/min or more, 30 nm/min or more, 35 nm/min or more, or the like). According to an embodiment of the abrasive grains of the present embodiment, in the evaluation method described in Experimental Examples described below, it is possible to obtain a polishing rate of silicon oxide in a pattern region with L/S=20/80 of, for example, 25.5 nm/min or more (preferably, 27 nm/min or more, 30 nm/min or more, 35 nm/min or more, 40 nm/min or more, 45 nm/min or more, 50 nm/min or more, or the like).

As an example of reasons why a high polishing rate is easily obtained, the following reason and the like are mentioned. However, the reasons why a high polishing rate is easily obtained are not limited to this content. That is, as the average value of the positron lifetime of the abrasive grains is smaller, an oxygen defect inside the abrasive grains is smaller. Further, when the oxygen defect inside the abrasive grains is small like this, the abrasive grains are less likely to be broken during polishing, and thus, the mechanical polishing force of the abrasive grains is easily maintained at a high level, so that a high polishing rate is easily obtained.

In the abrasive grains and the selection method therefor of the present embodiment, the average value of the positron lifetime (the positron lifetime of the abrasive grains) as measured by a positron annihilation method may be 500 ps or less, 450 ps or less, 400 ps or less, 390 ps or less, 380 ps or less, or 370 ps or less, from the viewpoint of easily adjusting the polishing rate of the material to be polished.

In the abrasive grains and the selection method therefor of the present embodiment, the average value of the positron lifetime (the positron lifetime of the abrasive grains) as measured by a positron annihilation method may be in the following range from the viewpoint of easily adjusting the polishing rate of the material to be polished or the viewpoint of easily increasing the polishing rate of the material to be polished (such as the polishing rate of silicon oxide in a blanket wafer or the polishing rate of silicon oxide in a pattern wafer). The average value of the positron lifetime may be 360 ps or less, 355 ps or less, 353 ps or less, 350 ps or less, 345 ps or less, 340 ps or less, 335 ps or less, or 330 ps or less. The average value of the positron lifetime may be 200 ps or more, 250 ps or more, 280 ps or more, 300 ps or more, 310 ps or more, 320 ps or more, 325 ps or more, 330 ps or more, 335 ps or more, 340 ps or more, 345 ps or more, 350 ps or more, or 353 ps or more.

From these viewpoints, the average value of the positron lifetime may be 200 to 500 ps, 200 to 360 ps, 200 to 350 ps, 200 to 330 ps, 300 to 500 ps, 300 to 360 ps, 300 to 350 ps, 300 to 330 ps, 330 to 500 ps, 330 to 360 ps, 330 to 350 ps, 350 to 500 ps, or 350 to 360 ps.

The selection method for abrasive grains of the present embodiment includes a selection step of selecting abrasive grains on the basis of an average value of a positron lifetime as measured by a positron annihilation method. In the selection step, abrasive grains may be selected on the basis of whether or not the average value of the positron lifetime is in any of the aforementioned ranges (for example, whether or not the average value of the positron lifetime is 360 ps or less).

The abrasive grains of the present embodiment have any numerical value as the crystallite diameter depending on the use application. In the selection step of the selection method for abrasive grains of the present embodiment, abrasive grains may be selected on the basis of the crystallite diameter, in addition to the average value of the positron lifetime. In the selection step, abrasive grains may be selected on the basis of whether or not the crystallite diameter is in any of the ranges described below (for example, whether or not the crystallite diameter is 30 nm or more), in addition to the average value of the positron lifetime.

In the abrasive grains and the selection method therefor of the present embodiment, the crystallite diameter of the abrasive grains may be 10 nm or more, 15 nm or more, 20 nm or more, or 25 nm or more, from the viewpoint of easily adjusting the polishing rate of the material to be polished.

The present inventors have found that, by using abrasive grains having a crystallite diameter of 30 nm or more, a polishing rate of silicon oxide is more easily increased. It is presumed that a high polishing rate is easily obtained since the mechanical polishing force of the abrasive grains is easily maintained at a high level when the crystallite diameter of the abrasive grains is large. However, the reasons why a high polishing rate is easily obtained are not limited to this content.

In the abrasive grains and the selection method therefor of the present embodiment, the crystallite diameter of the abrasive grains may be in the following range from the viewpoint of easily adjusting the polishing rate of the material to be polished or the viewpoint of easily increasing the polishing rate of the material to be polished (such as the polishing rate of silicon oxide in a blanket wafer or the polishing rate of silicon oxide in a pattern wafer). The crystallite diameter may be 30 nm or more, 33 nm or more, 35 nm or more, 36 nm or more, 38 nm or more, or 40 nm or more. The crystallite diameter may be 100 nm or less, 90 nm or less, 80 nm or less, 70 nm or less, 60 nm or less, 55 nm or less, 50 nm or less, 45 nm or less, 42 nm or less, 40 nm or less, 38 nm or less, 36 nm or less, or 35 nm or less.

From these viewpoints, the crystallite diameter may be 10 to 100 nm, 10 to 50 nm, 10 to 40 nm, 20 to 100 nm, 20 to 50 nm, 20 to 40 nm, 30 to 100 nm, 30 to 50 nm, 30 to 40 nm, 35 to 100 nm, 35 to 50 nm, 35 to 40 nm, 36 to 100 nm, 36 to 50 nm, 36 to 40 nm, 40 to 100 nm, or 40 to 50 nm.

As the crystallite diameter of the abrasive grains, the average crystallite diameter of the abrasive grains can be used. The crystallite diameter of the abrasive grains can be measured by the method described in Experimental Examples described below. The crystallite diameter of the abrasive grains can be adjusted by the production conditions of the abrasive grains. For example, as the firing temperature of the cerium source when a raw material (raw material for obtaining abrasive grains) containing cerium is obtained is higher, there is a tendency that the crystallite diameter is larger.

A polishing liquid of the present embodiment contains the abrasive grains of the present embodiment and water, and may contain the abrasive grains selected by the selection method for abrasive grains of the present embodiment and water. The polishing liquid of the present embodiment may contain a component (for example, various components described later) other than the abrasive grains and water, in addition to the abrasive grains and water. A multi-pack polishing liquid of the present embodiment has a liquid A (first liquid) containing the abrasive grains of the present embodiment and water, and a liquid B (second liquid) containing a component (for example, various components described later) other than the abrasive grains and water, and water. The abrasive grains of the liquid A may be the abrasive grains selected by the selection method for abrasive grains of the present embodiment. The liquid A may contain a component (for example, various components described later) other than the abrasive grains and water, and may not contain a component (for example, various components described later) other than the abrasive grains and water. In a method for producing the polishing liquid of the present embodiment, a polishing liquid may be obtained by mixing the abrasive grains of the present embodiment (for example, the abrasive grains obtained by the method for producing the abrasive grains of the present embodiment) and water, and a polishing liquid may be obtained by mixing the liquid A and the liquid B of the multi-pack polishing liquid of the present embodiment with each other. The liquid A can be obtained by mixing the abrasive grains of the present embodiment (for example, the abrasive grains obtained by the method for producing the abrasive grains of the present embodiment) and water. The liquid A may be a plurality of liquids, and may be, for example, a plurality of liquids in which the types of abrasive grains are different from each other. The liquid B may be a plurality of liquids, and may be, for example, a plurality of liquids in which the types of components other than the abrasive grains and water are different from each other.

The content of the abrasive grains may be in the following range on the basis of the total mass of the polishing liquid or the total mass of water. The content of the abrasive grains may be 0.01% by mass or more, 0.05% by mass or more, 0.1% by mass or more, 0.2% by mass or more, 0.3% by mass or more, 0.4% by mass or more, or 0.5% by mass or more, from the viewpoint of easily increasing the polishing rate of the material to be polished. The content of the abrasive grains may be 10% by mass or less, 8% by mass or less, 5% by mass or less, 3% by mass or less, 1% by mass or less, 0.8% by mass or less, or 0.5% by mass or less, from the viewpoint of easily suppressing an increase in viscosity of the polishing liquid, the aggregation of the abrasive grains, or the like. From these viewpoints, the content of the abrasive grains may be 0.01 to 10% by mass, 0.01 to 5% by mass, 0.01 to 1% by mass, 0.05 to 10% by mass, 0.05 to 5% by mass, 0.05 to 1% by mass, 0.1 to 10% by mass, 0.1 to 5% by mass, or 0.1 to 1% by mass.

Water may be contained as a residue excluding other components from the polishing liquid. The content of the water may be in the following range on the basis of the total mass of the polishing liquid. The content of the water may be 90% by mass or more, 910% by mass or more, 92% by mass or more, 93% by mass or more, 94% by mass or more, 95% by mass or more, 96% by mass or more, 97% by mass or more, 98% by mass or more, or 99% by mass or more. The content of the water may be less than 100% by mass, 99.9% by mass or less, 99.8% by mass or less, 99.7% by mass or less, 99.6% by mass or less, or 99.5% by mass or less. From these viewpoints, the content of the water may be 90% by mass or more and less than 100% by mass, 95% by mass or more and less than 100% by mass, or 98% by mass or more and less than 100% by mass.

The polishing liquid of the present embodiment can contain a phosphate compound as necessary. The phosphate compound may be used as a dispersant for the abrasive grains. As the phosphate compound, at least one selected from the group consisting of a phosphate and a derivative thereof (a phosphate derivative) can be used. As the hydrogen phosphate compound, at least one selected from the group consisting of a hydrogen phosphate and a derivative thereof (a hydrogen phosphate derivative) can be used.

Examples of the phosphate include potassium phosphate, sodium phosphate, ammonium phosphate, and calcium phosphate, and specific examples thereof include tripotassium phosphate, trisodium phosphate, ammonium phosphate, and tricalcium phosphate. Examples of the phosphate derivative include sodium diphosphate, potassium diphosphate, potassium polyphosphate, ammonium polyphosphate, and calcium polyphosphate.

Examples of the hydrogen phosphate include potassium hydrogen phosphate, sodium hydrogen phosphate, ammonium hydrogen phosphate, and calcium hydrogen phosphate, and specific examples thereof include dipotassium hydrogen phosphate, disodium hydrogen phosphate, diammonium hydrogen phosphate, calcium hydrogen phosphate, potassium dihydrogen phosphate, sodium dihydrogen phosphate, ammonium dihydrogen phosphate, and calcium dihydrogen phosphate. Examples of the hydrogen phosphate derivative include potassium dodecyl hydrogen phosphate, sodium dodecyl hydrogen phosphate, and dodecylammonium hydrogen phosphate.

From the viewpoint of easily increasing the polishing rate of the material to be polished, the polishing liquid of the present embodiment may contain a hydrogen phosphate, and may contain ammonium dihydrogen phosphate.

The content of the phosphate compound may be in the following range on the basis of the total mass of the polishing liquid or the total mass of water. The content of the phosphate compound may be 0.00010% by mass or more, 0.0005% by mass or more, 0.0010% by mass or more, 0.002% by mass or more, 0.003% by mass or more, 0.004% by mass or more, 0.005% by mass or more, 0.008% by mass or more, or 0.01% by mass or more, from the viewpoint of easily increasing the polishing rate of the material to be polished. The content of the phosphate compound may be 1% by mass or less, 0.5% by mass or less, 0.1% by mass or less, 0.08% by mass or less, 0.05% by mass or less, 0.04% by mass or less, 0.03% by mass or less, 0.02% by mass or less, or 0.01% by mass or less, from the viewpoint of easily suppressing the aggregation of the abrasive grains. From these viewpoints, the content of the phosphate compound may be 0.0001 to 1% by mass, 0.0001 to 0.1% by mass, 0.0001 to 0.05% by mass, 0.001 to 1% by mass, 0.001 to 0.10% by mass, 0.001 to 0.05% by mass, 0.005 to 10% by mass, 0.005 to 0.10% by mass, or 0.005 to 0.05% by mass.

The content of the phosphate compound may be in the following range with respect to 100 parts by mass of the abrasive grains. The content of the phosphate compound may be 0.01 parts by mass or more, 0.05 parts by mass or more, 0.1 parts by mass or more, 0.3 parts by mass or more, 0.5 parts by mass or more, 0.8 parts by mass or more, 1 part by mass or more, 1.2 parts by mass or more, 1.5 parts by mass or more, 1.8 parts by mass or more, or 2 parts by mass or more, from the viewpoint of easily increasing the polishing rate of the material to be polished. The content of the phosphate compound may be 50 parts by mass or less, 30 parts by mass or less, 20 parts by mass or less, 10 parts by mass or less, 8 parts by mass or less, 5 parts by mass or less, 4 parts by mass or less, 3 parts by mass or less, 2.5 parts by mass or less, or 2 parts by mass or less, from the viewpoint of easily suppressing the aggregation of the abrasive grains. From these viewpoints, the content of the phosphate compound may be 0.01 to 50 parts by mass, 0.01 to 10 parts by mass, 0.01 to 5 parts by mass, 0.1 to 50 parts by mass, 0.1 to 10 parts by mass, 0.1 to 5 parts by mass, 0.5 to 50 parts by mass, 0.5 to 10 parts by mass, 0.5 to 5 parts by mass, 1 to 50 parts by mass, 1 to 10 parts by mass, or 1 to 5 parts by mass.

The polishing liquid of the present embodiment can contain a polymer as necessary. Examples of the polymer include a homopolymer (such as polyacrylic acid) of unsaturated carboxylic acid such as acrylic acid, methacrylic acid, maleic acid, fumaric acid, or itaconic acid; an ammonium salt or amine salt of this homopolymer; a copolymer of an unsaturated carboxylic acid such as acrylic acid, methacrylic acid, maleic acid, fumaric acid, or itaconic acid and a monomer such as alkyl acrylate (such as methyl acrylate or ethyl acrylate), hydroxyalkyl acrylate (such as hydroxyethyl acrylate), alkyl methacrylate (such as methyl methacrylate or ethyl methacrylate), hydroxyalkyl methacrylate (such as hydroxyethyl methacrylate), a styrene compound (such as styrene, alkyl styrene, or styrenesulfonic acid), vinyl acetate, or vinyl alcohol; and an ammonium salt or amine salt of this copolymer. The polishing liquid of the present embodiment may contain a copolymer having at least one selected from the group consisting of an acrylic acid and a methacrylic acid and a styrene compound as monomer units, and may contain a copolymer (styrene/acrylic acid copolymer) having styrene and an acrylic acid as monomer units.

The polishing liquid of the present embodiment can contain an acid component (note that, a compound corresponding to the phosphate compound is excluded) as necessary. Examples of the acid component include organic acids (excluding compounds corresponding to amino acids) such as propionic acid and acetic acid; inorganic acids such as nitric acid, sulfuric acid, hydrochloric acid, phosphoric acid, and boric acid; and amino acids such as glycine.

The polishing liquid of the present embodiment may contain a component other than the abrasive grains of the present embodiment, water, the phosphate compound, the polymer, and the acid component. Such a component is not particularly limited, and examples thereof include abrasive grains not containing cerium; and a basic compound.

The pH of the polishing liquid of the present embodiment may be in the following range from the viewpoint of easily increasing the polishing rate of the material to be polished. The pH of the polishing liquid may be 1.0 or more, 1.5 or more, 2.0 or more, 2.5 or more, 3.0 or more, 3.5 or more, 4.0 or more, 4.5 or more, 5.0 or more, 5.5 or more, 6.0 or more, 6.5 or more, 7.0 or more, more than 7.0, 7.5 or more, 8.0 or more, or 8.5 or more. The pH of the polishing liquid may be 12.0 or less, 11.5 or less, 11.0 or less, 10.5 or less, 10.0 or less, 9.5 or less, or 9.0 or less. From these viewpoints, the pH of the polishing liquid may be 1.0 to 12.0, 1.0 to 10.0, 1.0 to 9.0, 5.0 to 12.0, 5.0 to 10.0, 5.0 to 9.0, 7.0 to 12.0, 7.0 to 10.0, or 7.0 to 9.0. The pH of the polishing liquid of the present embodiment can be measured by the method described in Experimental Examples described below.

A polishing method of the present embodiment includes a polishing step of polishing a member to be polished by using the polishing liquid of the present embodiment (for example, the polishing liquid obtained by the method for producing the polishing liquid of the present embodiment). The polishing liquid to be used in the polishing step may be the polishing liquid obtained by mixing the liquid A (first liquid) and the liquid B (second liquid) of the multi-pack polishing liquid of the present embodiment. In the polishing step, the surface to be polished of the member to be polished can be polished. In the polishing step, at least a part of the material to be polished in the member to be polished can be removed by polishing. Examples of the material to be polished include insulating materials such as silicon oxide and silicon nitride. The member to be polished may contain silicon oxide, and may contain silicon oxide and silicon nitride. In the polishing step, a blanket wafer having no pattern may be polished, a pattern region in which a linear silicon nitride pattern with a line width of 50 μm and a linear silicon oxide pattern with a line width of 50 μm are alternately arranged may be polished, and a pattern region in which a linear silicon nitride pattern with a line width of 20 μm and a linear silicon oxide pattern with a line width of 80 μm are alternately arranged may be polished. The abrasive grains, the polishing liquid, the polishing method, and the like of the present embodiment are not limited to being used for polishing these members to be polished, and for example, may be used for polishing other pattern regions. The member to be polished is not particularly limited, may be a wafer (for example, a semiconductor wafer), and may be a chip (for example, a semiconductor chip). The member to be polished may be a wiring board and may be a circuit board.

A method for manufacturing a component of the present embodiment includes a component manufacturing step of obtaining a component by using the polished member polished by the polishing method of the present embodiment. A component of the present embodiment is a component obtained by the method for manufacturing a component of the present embodiment. The component of the present embodiment is not particularly limited, and may be an electronic component (for example, a semiconductor component such as a semiconductor package), may be a wafer (for example, a semiconductor wafer), and may be a chip (for example, a semiconductor chip). As an embodiment of the method for manufacturing a component of the present embodiment, in a method for manufacturing an electronic component of the present embodiment, an electronic component is obtained by using the polished member polished by the polishing method of the present embodiment. As an embodiment of the method for manufacturing a component of the present embodiment, in a method for manufacturing a semiconductor component of the present embodiment, a semiconductor component (for example, a semiconductor package) is obtained by using the polished member polished by the polishing method of the present embodiment. The method for manufacturing a component of the present embodiment may include a polishing step of polishing a member to be polished by the polishing method of the present embodiment before the component manufacturing step.

The method for manufacturing a component of the present embodiment may include, as an embodiment of the component manufacturing step, an individually dividing step of individually dividing the polished member polished by the polishing method of the present embodiment. The individually dividing step may be, for example, a step of dicing a wafer (for example, a semiconductor wafer) polished by the polishing method of the present embodiment to obtain chips (for example, semiconductor chips). As an embodiment of the method for manufacturing a component of the present embodiment, the method for manufacturing an electronic component of the present embodiment may include a step of obtaining an electronic component (for example, a semiconductor component) by individually dividing the polished member polished by the polishing method of the present embodiment. As an embodiment of the method for manufacturing a component of the present embodiment, the method for manufacturing a semiconductor component of the present embodiment may include a step of obtaining a semiconductor component (for example, a semiconductor package) by individually dividing the polished member polished by the polishing method of the present embodiment.

The method for manufacturing a component of the present embodiment may include, as an embodiment of the component manufacturing step, a connecting step of connecting (for example, electrically connecting) the polished member polished by the polishing method of the present embodiment to other body to be connected. The body to be connected that is connected to the polished member polished by the polishing method of the present embodiment is not particularly limited, may be the polished member polished by the polishing method of the present embodiment, and may be a body to be connected different from the polished member polished by the polishing method of the present embodiment. In the connecting step, the polished member and the body to be connected may be directly connected to each other (connected in a state where the polished member and the body to be connected are in contact with each other), and the polished member and the body to be connected may be connected via other member (such as a conductive member). The connecting step can be performed before the individually dividing step, after the individually dividing step, or before and after the individually dividing step.

The connecting step may be a step of connecting a polished surface of the polished member polished by the polishing method of the present embodiment to a body to be connected, and may be a step of connecting a connection surface of the polished member polished by the polishing method of the present embodiment to a connection surface of a body to be connected. The connection surface of the polished member may be a polished surface polished by the polishing method of the present embodiment. A connection body having the polished member and the connected body can be obtained by the connecting step. In the connecting step, in a case where the connection surface of the polished member has a metal portion, the body to be connected may be connected to the metal portion. In the connecting step, in a case where the connection surface of the polished member has a metal portion and the connection surface of the body to be connected has a metal portion, the metal portions may be connected to each other. The metal portion may contain, for example, copper.

A device (for example, an electronic device such as a semiconductor device) of the present embodiment has at least one selected from the group consisting of the polished member polished by the polishing method of the present embodiment and the component of the present embodiment.

### EXAMPLES

Hereinafter, the present disclosure will be specifically described on the basis of Experimental Examples; however, the present disclosure is not limited to these Experimental Examples.

### (Production of Cerium Oxide Particles)

A cerium source of Table 1 was fired for 1 hour at 800° C. in air by using an electric furnace to obtain cerium oxide particles (ceria particles).

A cerium complex of trimesic acid (metal organic framework) was produced by the following procedure. First, 34.7 g (165 mmol) of trimesic acid (1,3,5-BTC: 1,3,5-Benzene tricarboxylic acid, manufactured by Tokyo Chemical Industry Co., Ltd.) was added to 480 mL of a water/ethanol mixed solvent (mass ratio 1:1) to prepare a trimesic acid solution. Furthermore, 71.2 g (164 mmol) of cerium nitrate hexahydrate (manufactured by FUJIFILM Wako Pure Chemical Corporation) was added to 20 mL of water to prepare a cerium nitrate aqueous solution. The aforementioned cerium nitrate aqueous solution was added to the aforementioned trimesic acid solution to obtain a mixed liquid A, and then the mixed liquid A was stirred at 25° C. and 400 rpm for hours by using a magnetic stirrer. After a solid matter (white precipitate) was generated in the mixed liquid A, the mixed liquid A was left to stand still for 15 hours. After the mixed liquid A was stirred to re-disperse the solid matter, the mixed liquid A was placed into a 50 mL centrifuge tube, and centrifugal separation was performed at 5000 rpm for 5 minutes. After the supernatant solution after the centrifugal separation was transferred to another container, 25.4 g (251 mmol, 35 mL) of triethylamine (manufactured by FUJIFILM Wako Pure Chemical Corporation) was slowly added to the supernatant solution while stirring the supernatant solution at 25° C. and 700 rpm to increase the pH from 1.0 to 8.4, thereby obtaining a mixed liquid B in which the solid matter (white precipitate) was generated. After the mixed liquid B was stirred to re-disperse the solid matter, the mixed liquid B was placed into a 50 mL centrifuge tube, and centrifugal separation was performed at 5000 rpm for 5 minutes. After the centrifugal separation, the supernatant solution was removed, and 35 mL of a water/ethanol mixed solvent (mass ratio 1:1) was placed into the centrifuge tube. After the solid matter (white precipitate) was re-dispersed, centrifugal separation was performed at 5000 rpm for 5 minutes. This washing operation (operation of adding the water/ethanol mixed solvent after removing the supernatant solution, and performing centrifugal separation) was performed twice in total, and then the solvent (washing solution) was removed. Drying was performed with a heat vacuum drier for 39 hours to obtain 21.5 g (44.3 mmol) of white solids (Ce(1,3,5-BTC)·6H₂O) of the cerium complex of trimesic acid.

### (Production of Abrasive Grains)

A suspension was obtained by mixing the aforementioned cerium oxide particles, ammonium dihydrogen phosphate, and water. The content of the cerium oxide particles was 5% by mass on the basis of the total mass of the suspension, and the content of the ammonium dihydrogen phosphate was 2 parts by mass with respect to 100 parts by mass of the cerium oxide particles.

The aforementioned suspension was subjected to a dispersion treatment for 30 minutes by using an ultrasonic dispersing apparatus (manufactured by SND Co., Ltd., trade name “US-105”). Next, the cerium oxide particles in the aforementioned suspension were subjected to a pulverization treatment (wet pulverization) by using a bead mill (manufactured by Ashizawa Finetech Ltd., trade name: LABSTAR Mini, Model No.: DMS65) until the particle diameter reached about 200 nm.

After the aforementioned pulverization treatment, a classification treatment was performed by using a centrifugal separator (manufactured by Eppendorf Himac Technologies Co., Ltd., trade name: CF-15R) to remove coarse particles in the aforementioned suspension so that the particle diameter was aligned to about 150 nm, thereby obtaining an aqueous dispersion of the abrasive grains. This classification treatment was performed by placing 50 g of the suspension into a centrifuge tube and performing centrifugal separation at 1500 to 3700 min⁻¹ for 5 minutes.

### (Measurement of Positron Lifetime of Abrasive Grains)

The average value of the positron lifetime of the aforementioned abrasive grains was measured by the following procedure. The measurement results are shown in Table 1.

The aforementioned aqueous dispersion was subjected to centrifugal separation by using a centrifugal separator (manufactured by Eppendorf Himac Technologies Co., Ltd., trade name: CF-15R) to remove the supernatant solution, thereby obtaining a solid matter. This centrifugal separation was performed by placing 50 g of the suspension into a centrifuge tube and performing centrifugal separation at 8000 min⁻¹ for 25 minutes. Then, this solid matter was dried at 30° C. for 15 hours by using a vacuum constant temperature drier (manufactured by Yamato Scientific Co., Ltd., trade name: ADP200), and the solid matter was then crushed with a mortar to obtain abrasive grains.

The aforementioned abrasive grains were filled in a powder measurement cell to a height of 5 mm, and the positron lifetime (positron annihilation lifetime) was measured by a positron annihilation method under the conditions below. A three-component analysis including the lifetime and intensity of Kapton and an adhesive contained in a radiation source was performed by using the measured value of the positron lifetime. τ1 that is the lifetime of Kapton contained in the radiation source is known to be 0.38 ns, which is close to the positron lifetime of a sample, and thus, in order to accurately measure the positron lifetime of the sample, it is necessary to fix a intensity I1 of the Kapton contained in the radiation source. Since I1 is known to be about 20 to 35%, I1 was fixed at 30% in this measurement. τ2 is the lifetime of the adhesive contained in the radiation source, and I2 corresponding to this lifetime indicates the intensity of the adhesive contained in the radiation source. The lifetime derived from cerium oxide obtained by three-component analysis was obtained as the average value (τ3) of the positron lifetime, and the intensity corresponding thereto was obtained as 13 (I1+I2+I3=100%).

### {Measurement Conditions}

Measuring apparatus: Trade name “PSA Type L-II” manufactured by TOYO SEIKO CO., LTD.
Positron radiation source: Thin-film positron radiation source (manufactured by Japan Radioisotope Association).
Total count number: 1000000 counts

### (Measurement of Crystallite Diameter of Abrasive Grains)

Abrasive grains were obtained from the aforementioned aqueous dispersion in the same manner as in the aforementioned measurement of the positron lifetime. Next, the diffraction spectra of the abrasive grains were obtained in a range of 2θ=27 to 30° by using a powder X-ray diffractometer (XRD, manufactured by Rigaku Corporation, Ultima IV, divergence height limiting slit: 10 mm, divergence slit: 1°, scattering slit: 1°, absorber: Cukp, light receiving slit: 0.15 mm, output: 40 kV/20 mA). The measurement was performed under the conditions of a measurement interval of 0.02°/step and a scanning speed of 4 steps/s, and the crystallite diameter (average value) was calculated by the half-width of the CeO₂(111) peak and the Scherrer equation. As the Scherrer constant, 0.89 was used. The measurement results are shown in Table 1.

### (Preparation of Polishing Liquid)

A polishing liquid was obtained by diluting the aforementioned aqueous dispersion with water. On the basis of the total mass of the polishing liquid, the content of the abrasive grains was 0.5% by mass, and the content of the ammonium dihydrogen phosphate was 0.01% by mass.

The pH of the polishing liquid was measured by using a compact pH meter (manufactured by HORIBA, Ltd., trade name: LAQUA twin). The pH meter was subjected to two-point calibration by using two kinds of pH buffer solutions (pH 4.01 and pH 6.86) as standard buffer solutions, subsequently the sensor of the pH meter was placed into the polishing liquid, and the pH was measured after the pH was stabilized. The liquid temperature of both the standard buffer solution and the polishing liquid was 25° C. The measurement results are shown in Table 1.

### (Evaluation of Polishing Properties)

A blanket wafer (BKW) was produced by the following procedure. First, a ϕ200 mm wafer with no pattern having a silicon oxide film (SiO₂, initial film thickness: 2000 nm) on a surface thereof was prepared. Next, this wafer was cut into 20 mm×20 mm to obtain a blanket wafer for polishing.

A pattern wafer (PTW) was produced by the following procedure. First, trade name “8” SEMATECH864” (Stop on Nitride) manufactured by SEMATECH was prepared. This wafer is a wafer obtained by forming a SiN film as a stopper film on a part of a silicon substrate having a diameter of 200 mm, etching the silicon substrate in the portion without the SiN film by 350 nm to form a concave portion, and then depositing a 600-nm SiO₂ film on the stopper film and in the concave portion by plasma CVD. Next, this wafer was cut into 20 mm×20 mm to obtain a pattern wafer having a pattern region in which the line width (L/S; unit μm) of the SiN pattern (Line) and the SiO₂ pattern (Space) was 50/50 and a pattern region in which the line width (L/S; unit μm) of the SiN pattern (Line) and SiO₂ pattern (Space) was 20/80.

In a polishing apparatus (manufactured by NANO FACTOR Co., Ltd., trade name: FACT-200), the aforementioned wafer (the blanket wafer or the pattern wafer) was attached to a holder for mounting a base substrate to which an adsorption pad was attached. The holder was placed on a platen to which a polishing pad (manufactured by NITTA DuPont Incorporated, trade name: IC1010) was attached such that the surface to be polished faced the polishing pad. The wafer was pressed against the polishing pad at a polishing load of 7 psi (1 psi=6.9 kPa) while supplying the aforementioned polishing liquid onto the polishing pad at an amount supplied of 5 mL/min. At this time, polishing was performed for 60 seconds by rotating the platen at 120 min⁻¹ and rotating the holder together with the platen. The wafer after polishing was thoroughly washed with pure water and then dried.

In the blanket wafer, the film thicknesses at a total of five measuring points, i.e., the center point of the wafer after polishing and four points away from the center point in a direction of diagonal line by 7.1 cm were measured by using a film thickness measuring apparatus (manufactured by Toho Technology Corporation, trade name: TohoSpec3100). The difference between the average value of these film thicknesses and the film thickness at the center point of the wafer before polishing was obtained as a change amount in film thickness to determine the polishing rate of the blanket wafer. The results are shown in Table 1.

In the pattern wafer, the polishing rate of silicon oxide was determined by measuring a change amount of thickness before and after polishing of SiO₂ (1 location) on SiN in the pattern region with L/S=50/50 and the pattern region with L/S=20/80 by using a film thickness measuring apparatus (manufactured by Toho Technology Corporation, trade name: TohoSpec3100). The results are shown in Table 1.

TABLE 1

| | | Experimental Example | | | | |
|---|---|---|---|---|---|---|
| | | 1 | 2 | 3 | 4 | 5 |
| | | Cerium source | | | | |
| | | Cerium | | | | |
| | | complex of | Cerium | Cerium | Cerium | Cerium |
| | | trimesic acid | hydroxide | carbonate | oxycarbonate | acetate |
| Positron lifetime [ps] | | 327.5 | 332.4 | 351.6 | 354.7 | 368.5 |
| Crystallite diameter [nm] | | 38.1 | 35.6 | 40.2 | 34.7 | 25.6 |
| pH | | 8.61 | 8.53 | 8.63 | 8.58 | 8.58 |
| Polishing rate | BKW | 119.0 | 28.2 | 129.9 | 110.6 | 21.3 |
| [nm/min] | PTW (50/50) | 35.3 | 17.0 | 24.3 | 33.1 | 12.9 |
| | PTW (20/80) | 53.5 | 25.6 | 27.8 | 39.8 | 25.1 |

1. A selection method for abrasive grains, wherein
the abrasive grains contain cerium, and
the abrasive grains are selected on the basis of an average value of a positron lifetime as measured by a positron annihilation method.

2. The selection method for abrasive grains according to claim 1, wherein the abrasive grains contain cerium oxide.

3. Abrasive grains comprising cerium, wherein
an average value of a positron lifetime as measured by a positron annihilation method is 360 ps or less.

4. The abrasive grains according to claim 3, wherein the average value of the positron lifetime as measured by the positron annihilation method is 300 to 360 ps.

5. The abrasive grains according to claim 3, wherein a crystallite diameter is 30 nm or more.

6. The abrasive grains according to claim 3, wherein a crystallite diameter is 36 to 50 nm.

7. The abrasive grains according to claim 3, comprising cerium oxide.

8. The abrasive grains according to claim 3, comprising cerium oxide derived from a cerium complex of trimesic acid.

9. The abrasive grains according to claim 3, comprising cerium oxide derived from cerium hydroxide.

10. The abrasive grains according to claim 3, comprising cerium oxide derived from cerium carbonate.

11. The abrasive grains according to claim 3, comprising cerium oxide derived from cerium oxycarbonate.

12. A polishing liquid comprising: the abrasive grains according to claim 3; and water.

13. A multi-pack polishing liquid comprising: a first liquid containing the abrasive grains according to claim 3 and water; and a second liquid containing a component other than the abrasive grains and water, and water.

14. A polishing method, comprising: polishing a member to be polished by using the polishing liquid according to claim 12.

15. The polishing method according to claim 14, wherein the member to be polished contains silicon oxide.

16. A method for manufacturing a component, comprising: obtaining a component by using a polished member polished by the polishing method according to claim 14.

17. A method for manufacturing a semiconductor component, comprising: obtaining a semiconductor component by using a polished member polished by the polishing method according to claim 14.

18. The polishing liquid according to claim 12, a content of the abrasive grains is 0.1 to 1% by mass on the basis of a total mass of the polishing liquid.

19. The polishing liquid according to claim 12, a pH of the polishing liquid is 6.0 to 11.0.

20. The polishing liquid according to claim 12, a pH of the polishing liquid is 7.0 to 9.0.
